(19) United States
(12) Patent Application Publication
(10) Pub. No.: US 2026/0179880 A1
(43) Pub. Date: Jun. 25, 2026

(54) IMPEDANCE MATCHING NETWORK, PLASMA CONTROL SYSTEM, AND IMPEDANCE MATCHING METHOD

(71) Applicant: Rohde & Schwarz GmbH & Co. KG, Muenchen (DE)

(72) Inventors: Alexander Meixner, Muenchen (DE); Florian Ohnimus, Muenchen (DE); Mathias Pietzka, Muenchen (DE)

(21) Appl. No.: 18/990,915

(22) Filed: Dec. 20, 2024

(51) Int. Cl. H01J 37/32

(52) U.S. Cl. CPC H01J 37/32183; H01J 37/32935

(57) ABSTRACT

An impedance matching network comprising an input port connectable to a radio frequency (RF) generator circuit and an output port connectable to a load. A transmission line is connected between the output port to the input port. The impedance matching network comprises an impedance matching circuit comprising a primary circuit, a secondary circuit, at least one inductance, at least one reactance, and a switching circuit. The primary circuit is connected to the transmission line or is arranged in the transmission line. The secondary circuit comprises the at least one reactance. The at least one inductance is configured to couple the primary circuit with the secondary circuit. The switching circuit is configured to selectively electrically connect or disconnect the secondary circuit.

### FIELD OF THE DISCLOSURE

Embodiments of the present disclosure generally relate to an impedance matching network for plasma processes. Embodiments of the present disclosure further relate to a plasma control system, as well as to an impedance matching method of matching an impedance for a plasma process.

### BACKGROUND

For igniting and maintaining a plasma, usually an RF power generator is connected to a chamber feed unit that transfers the power of the RF signal generated by the RF power generator into a plasma chamber containing the plasma.

As the impedance of the plasma usually differs significantly from commonly used interface impedances (e.g. 50 Ohm), and as the impedance can vary significantly over time and power level, it is common in the state of the art to provide an impedance matching network in order to optimize the efficiency of the power transfer into the plasma.

In an embodiment, before the plasma is initiated, the load impedance presented to the RF power generator is extremely high, while the impedance of a stable plasma after initiation is low. The change from the high-impedance state to the low-impedance state of the plasma happens rather fast during ignition of the plasma, requiring a fast adaptation of the impedance of the impedance matching network.

Thus, there is a need for an impedance matching network, a plasma control system, and a method of impedance matching for a plasma process that enable a fast and accurate tuning of the impedance.

### SUMMARY

The following summary of the present disclosure is intended to introduce different concepts in a simplified form that are described in further detail in the detailed description provided below. This summary is neither intended to denote essential features of the present disclosure nor shall this summary be used as an aid in determining the scope of the claimed subject matter.

Embodiments of the present disclosure provide an impedance matching network for plasma processes. In an embodiment, the impedance matching network comprises an input port being connectable to a radio frequency (RF) generator circuit and an output port being connectable to a load. The impedance matching network also comprises a transmission line that connects the output port to the input port.

The impedance matching network further comprises an impedance matching circuit that comprises a primary circuit, a secondary circuit, at least one inductance, at least one reactance, and a switching circuit. The primary circuit is connected to the transmission line or is arranged in the transmission line. The secondary circuit comprises the at least one reactance. The at least one inductance is configured to couple the primary circuit with the secondary circuit. The at least one inductance comprises a plurality of secondary windings being arranged at the secondary circuit. The switching circuit is configured to selectively electrically connect at least one winding of the plurality of secondary windings to the secondary circuit or electrically disconnect at least one winding of the plurality of secondary windings from the secondary circuit.

The term “electrically connect” is understood to denote that a direct connection via an electrical conductor is established. On the other hand, the term “electrically disconnect” is understood to denote that there is no direct electrical connection via an electrical conductor connecting the respective components. However, the respective components can still be coupled, e.g. via an inductive coupling. Further, the respective components may be connected to a common reference potential, e.g. a common ground potential.

The impedance matching network is based on the idea to couple the at least one reactance to and/or into the transmission line indirectly, namely via the at least one inductance, thereby adapting an impedance of the impedance matching circuit.

The inventors recognized that using the inductance in combination with a switching circuit configured to selectively electrically connect or disconnect the at least one secondary winding allows to precisely tailor currents and voltages applied to the at least one reactance. On one hand, this allows to precisely set the impedance of the impedance matching network. On the other hand, as the currents and voltages applied to the at least one reactance can be set precisely, overloading of the at least one reactance can be prevented reliably, which increases the lifetime of the impedance matching circuit, for example of the at least one reactance.

Further, the inventors recognized that an increased tuning range, i.e. an increased range of impedances of the impedance matching network, is achievable with the examples of impedance matching network disclosed herein, as different numbers of secondary windings can be engaged by the switching circuit. Thus, an enhanced matching performance is provided without a trade-off for tuning speed.

Moreover, it has turned out that fewer components are necessary in order to achieve a desired impedance tuning range, thereby reducing the manufacturing costs of the impedance matching network.

According to an example embodiment of the present disclosure, the impedance matching circuit comprises a transformer circuit coupling the primary circuit with the secondary circuit, wherein the transformer circuit comprises the at least one inductance. Thus, by selectively connecting or disconnecting the at least one secondary winding, a transformation ratio of the transformer circuit is adapted, as the number of secondary windings is changed.

Therein and hereinafter, the term “transformer circuit” is understood to denote an electrical circuit or an electrical component that is configured to transform electrical energy from the primary circuit to the secondary circuit.

In an embodiment, the primary circuit and the secondary circuit may be coupled only via the transformer circuit. Accordingly, the primary circuit and the secondary circuit may be galvanically isolated from each other. Alternatively, the primary circuit and the secondary circuit may be connected to a common reference potential, for example to a common ground potential.

In another example embodiment, the transformer circuit comprises at least one primary winding, wherein the at least one primary winding is arranged at the primary circuit. Accordingly, electrical energy is transferred between the primary circuit and the secondary circuit via the at least one primary winding and the secondary winding(s) coupled to the secondary circuit by the switching circuit.

According to an aspect of the present disclosure, the at least one reactance comprises, for example, at least one capacitor. However, the at least one reactance may alternatively or additionally comprise at least one inductor.

A further aspect of the present disclosure provides, for example, that the switching circuit comprises at least one solid-state switch. With solid-state switches, for example, fast switching times are achievable. Moreover, solid-state switches have particularly long operational lifetime. Solid-state switches may also be called a solid state relay (SSR).

In an embodiment, the switching circuit may be or comprise a mechanical switch, a micro-electromechanical systems (MEMS) switch, a semiconductor switch, a PIN diode, a MOSFET, or other suitable type of electronic circuitry.

In an embodiment, the switching circuit comprises a plurality of switches being arranged in parallel, wherein each switch of the plurality of switches is configured to selectively connect at least one winding of the plurality of secondary windings to the secondary circuit or disconnect at least one winding of the plurality of secondary windings from the secondary circuit. With the plurality of switches, the number of secondary windings connected to the secondary circuit can be adapted in a stepwise manner. This allows to adapt the impedance of the impedance matching network in a step-wise manner.

In an embodiment, by providing a sufficient number of switches and corresponding secondary windings, the number of secondary windings connected to the secondary circuit can be adapted quasi-continuously. Thus, the impedance of the impedance matching network can be adapted quasi-continuously.

An aspect of the present disclosure provides, for example, that each switch of the plurality of switches is established as a solid-state switch. As the solid-state switches provide particularly fast switching times, the number of secondary windings connected to the secondary circuit can be adapted particularly fast by the plurality of switches.

According to another aspect of the present disclosure, the primary circuit, for example, is arranged between the input port and the output port. Accordingly, the output port is connected to the input port via the primary circuit, wherein the at least one reactance is coupled to the output port and the input port via the at least one inductance.

In other words, the primary circuit may be part of the transmission line connecting the output port with the input port, wherein the at least one reactance is coupled into the transmission line via the at least one inductance.

In an embodiment, the primary circuit is arranged between a contact point to the transmission line and a common reference potential. Accordingly, the primary circuit may connect the transmission line to the common reference potential, wherein the at least one reactance is coupled to the transmission line via the at least one inductance.

In an embodiment, the common reference potential may be a ground potential.

In an embodiment, the at least one reactance is adjustable. For example, at least one motor being connected to the at least one adjustable reactance may be provided, wherein the at least one motor is configured to adapt the impedance of the at least one adjustable reactance, for example wherein the at least one adjustable reactance is a variable vacuum capacitor, VVC. Such motor-driven reactances allow to adjust their impedance continuously and over a wide impedance range. Accordingly, the impedance of the impedance matching network can be adapted continuously and over a wide impedance range.

Alternatively or additionally, in the case of the at least one reactance comprising a capacitor, the capacitor may comprise a reconfigurable dielectric and/or permeable material, for example barium strontium titanite (BST), wherein the capacitance of the respective capacitor changes based on the bias voltage applied, or based on an electric and/or magnetic field caused by the bias voltage.

In a certain example, at least one of the adjustable reactances may be established as a BST varactor.

Alternatively or additionally, the impedance matching circuit may comprise a plurality of reactances, wherein the plurality of reactances can be selectively connected to the secondary winding(s) of the at least one inductance, e.g. via a set of switches.

Embodiments of the present disclosure further provide a plasma control system. In an embodiment, the plasma control system comprises at least one impedance matching network according to any one of the examples described above.

Regarding the advantages and further properties of the plasma control system, reference is made to the explanations given above with respect to the impedance matching network, which also hold for the plasma control system and vice versa.

According to an aspect of the present disclosure, the plasma control system, for example, further comprises at least one RF generator circuit, and at least one chamber feed unit. In an embodiment, the at least one chamber feed unit is configured to feed energy into plasma, wherein the input port of the at least one impedance matching network is connected to the at least one RF generator circuit, and wherein the output port of the at least one impedance matching network is connected to the at least one chamber feed unit. Accordingly, the impedance matching network may be configured to adapt the impedance of the load presented to the RF generator circuit, such that the energy fed into the plasma by the chamber feed unit is maximized, while reflection losses are minimized.

For example, the chamber feed unit may be established as an electrode generating an electric field and/or as an inductive coil generating a magnetic field.

According to another aspect of the present disclosure, the plasma control system further comprises, for example, a first measurement circuit, a second measurement circuit, and a control circuit. The first measurement circuit is connected to the at least one RF generator circuit, wherein the first measurement circuit is configured to determine at least one first measurement parameter based on at least one RF signal generated by the at least one RF generator circuit. The second measurement circuit is connected to the output port of the at least one impedance matching network, wherein the second measurement circuit is configured to determine at least one second measurement parameter based on at least one output signal of the at least one impedance matching network. The control circuit is configured to control the at least one impedance matching network based on the at least one first measurement parameter and based on the at least one second measurement parameter.

In an embodiment, the control circuit may be configured to control the impedance matching circuit described above to adapt its respective impedance, namely by controlling the switching circuit to selectively connect or disconnect the at least one secondary winding.

Embodiments of the present disclosure further provide an impedance matching method of matching an impedance for a plasma process. In an embodiment, the impedance matching method comprises generating, by at least one RF generator circuit, at least one RF signal; processing, by at least one impedance matching network, the at least one RF signal, thereby obtaining at least one output signal; feeding the at least one output signal to at least one chamber feed unit; determining, by a first measurement circuit, at least one first measurement parameter based on the at least one RF signal; determining, by a second measurement circuit, at least one second measurement parameter based on the at least one output signal; and controlling, by a control circuit, the at least one impedance matching network to adapt an impedance of the at least one impedance matching network based on the at least one first measurement parameter and based on the at least one second measurement parameter.

Regarding the advantages and further properties of the impedance matching method, reference is made to the explanations given above with respect to the impedance matching network and the plasma control system, which also hold for the plasma control system and vice versa.

According to an aspect of the present disclosure, the impedance matching network comprises, for example, an input port being connected to the RF generator circuit. The impedance matching network further comprises an output port being connected to the chamber feed unit. The impedance matching network further comprises a transmission line, wherein the transmission line connects the output port to the input port. The impedance matching network comprises an impedance matching circuit, wherein the impedance matching circuit comprises a primary circuit, a secondary circuit, at least one inductance, at least one reactance, and a switching circuit. The primary circuit is connected to the transmission line or is arranged in the transmission line. The secondary circuit comprises the at least one reactance. The at least one inductance is configured to couple the primary circuit with the secondary circuit, wherein the at least one inductance comprises a plurality of secondary windings being arranged at the secondary circuit. The switching circuit is configured to selectively electrically connect at least one winding of the plurality of secondary windings to the secondary circuit or electrically disconnect at least one winding of the plurality of secondary windings from the secondary circuit.

In an embodiment, the impedance matching network may be established according to any one of the embodiments described above.

Regarding the advantages and further properties, reference is made to the explanations given above with respect to the impedance matching network.

In an embodiment, the switching circuit is controlled to selectively electrically connect the at least one secondary winding of the plurality of windings to the secondary circuit or electrically disconnect the at least one winding of the plurality of windings from the secondary circuit by the control circuit based on the at least one first measurement parameter and based on the at least one second measurement parameter. More precisely, the control circuit controls the switch or the plurality of switches of the switching circuit to selectively electrically connect or disconnect the secondary winding(s) to/from the secondary circuit.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows a plasma control system according to an embodiment of the present disclosure;

FIG. 2 schematically shows an example embodiment of an impedance matching network of the plasma control system of FIG. 1;

FIG. 3 schematically shows another embodiment of an impedance matching network of the plasma control system of FIG. 1;

FIG. 4 schematically shows another embodiment of an impedance matching circuit of the impedance matching network of FIG. 2 or 3; and

FIG. 5 shows a representative flow chart of an impedance matching method according to an embodiment of the present disclosure.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

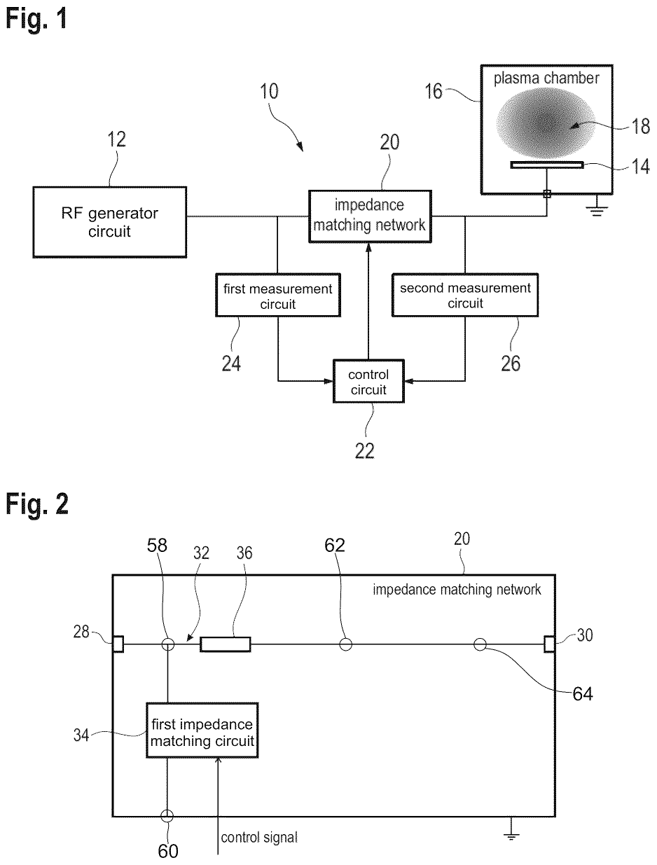

FIG. 1 schematically shows a plasma control system 10. As shown in FIG. 1, the system 10 comprises an RF generator circuit 12 and a chamber feed unit 14, wherein the chamber feed unit 14 is located in a plasma chamber 16. In general, the RF generator circuit 12 is configured to generate an RF signal that is forwarded to the chamber feed unit 14. The chamber feed unit 14 feeds the RF signal into plasma 18 contained in the plasma chamber 16, thereby initiating and/or maintaining the plasma 18. For example, the chamber feed unit 14 may be an electrode generating an electric field or an inductive coil generating a magnetic field.

In order to minimize losses and maximize the amount of energy fed into the plasma 18, the plasma control system 10 comprises an impedance matching network 20. In an embodiment, an impedance of the impedance matching network 20 can be adapted in order to account for a varying impedance of the plasma 18. As shown in FIG. 1, the impedance matching network 20 is interconnected between the RF generator circuit 12 and the chamber feed unit 14, such that the impedance of a load presented to the RF generator circuit 12 can be adapted by the impedance matching network 20. As will be described in more detail below, the impedance of the impedance matching network 20 is controlled by a control circuit 22.

In general, the control circuit 22 controls the impedance matching network 20 based on at least one first measurement parameter obtained by a first measurement circuit 24 and based on at least one second measurement parameter obtained by a second measurement circuit 26. Therein, the first measurement circuit 24 receives an input signal of the impedance matching network 20 and determines the at least one first measurement parameter based on the input signal of the impedance matching network 20. In an embodiment, the input signal of the impedance matching network 20 corresponds to the RF signal generated by the RF generator circuit 12.

In an embodiment, the second measurement circuit 26 receives an output signal of the impedance matching network 20, and determines the at least one second measurement parameter based on the output signal of the impedance matching network 20. In an embodiment, the output signal of the impedance matching network 20 corresponds to the RF signal generated by the RF generator circuit 12 and processed by the impedance matching network 20.

FIG. 2 schematically shows an example embodiment of the impedance matching network 20 in more detail. As shown in FIG. 2, the impedance matching network 20 comprises an input port 28 that is connected to the RF generator circuit 12. The impedance matching network 20 further comprises an output port 30 that is connected to the chamber feed unit 14. Between the input port 28 and the output port 30, a transmission line 32 is provided that connects the input port 28 to the output port 30.

In general, the impedance matching network 20 is configured to forward the RF signal generated by the RF generator circuit 12 from the input port 28 to the output port 30 while matching an impedance presented to the RF generator circuit 12.

In an embodiment, the impedance matching network 20 further comprises a first impedance matching circuit 34. In general, the first impedance matching circuit 34 is configured to selectively couple at least one reactance to and/or into the transmission line 32. The at least one reactance may comprise at least one capacitance and/or at least one inductance. In an embodiment, the at least one reactance may comprise a plurality of capacitances and/or a plurality of inductances.

In the example embodiment shown in FIG. 2, the first impedance matching circuit 34 is interconnected between a contact point 58 to the transmission line 32 and a common reference potential 60. Accordingly, the first impedance matching circuit 34 is configured to selectively couple the at least one reactance between the transmission line 32 and the common reference potential 60.

For example, the common reference potential 60 may be a ground potential. However, it is to be understood that the first impedance matching circuit 34 may alternatively be provided in the transmission line 32, wherein the first impedance matching circuit 34 may be interconnected between the input port 28 and the output port 30.

In an embodiment, the first impedance matching circuit 34 may be interconnected between a first point 62 of the transmission line 32 and a second point 64 of the transmission line 32, wherein the second point 64 may coincide with the output port 30.

In this case, the first impedance matching circuit 34 may be configured to selectively couple the at least one reactance into the transmission line 32 between the input port 28 and the output port 30.

As is indicated in FIG. 2 and as will be described in more detail below, the first impedance matching circuit 34 may receive a control signal from the control circuit 22, wherein the control signal controls the first impedance matching circuit 34 to adapt its impedance.

In an embodiment, the impedance matching network 20 may comprise at least one further reactance 36, for example at least one further inductance, that is provided in the transmission line 32. The at least one further reactance 36 may be provided downstream of the contact point 58 and/or upstream of the first point 62.

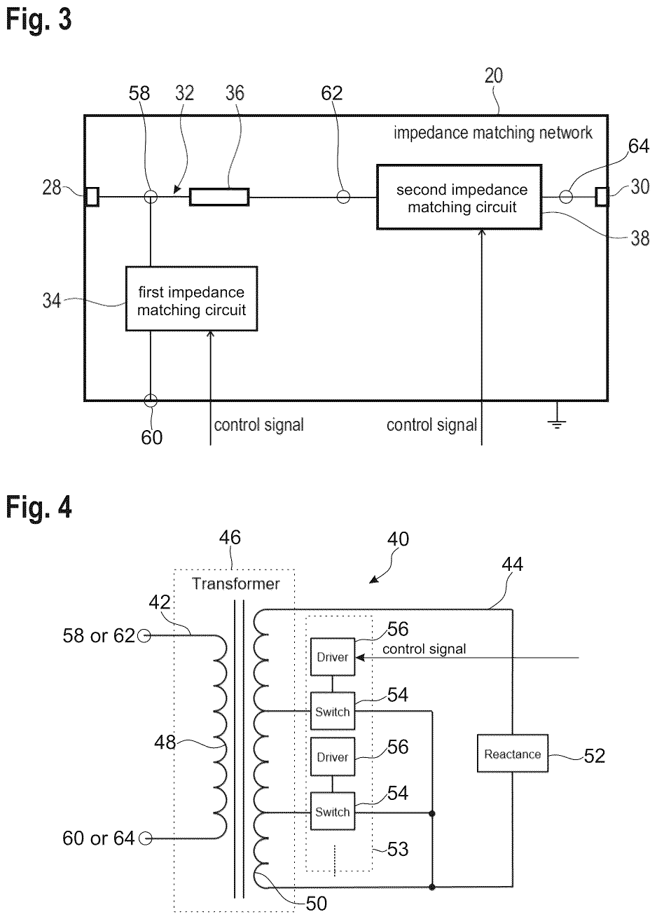

FIG. 3 shows another embodiment of the impedance matching network 20, wherein the impedance matching network 20 comprises a second impedance matching circuit 38. Therein, the first impedance matching circuit 34 is interconnected between the transmission line 32 and the common reference potential 60. The second impedance matching circuit 38 is provided in the transmission line 32, i.e. the second impedance matching circuit 38 is interconnected between the input port 28 and the output port 30.

In an embodiment, the second impedance matching circuit is interconnected between the first point 62 and the second point 64.

In the example embodiment shown in FIG. 3, the first impedance matching circuit 34 is configured to selectively couple at least one reactance to the transmission line 32. The second impedance matching circuit 38 is configured to selectively couple at least one reactance into the transmission line 32.

As is indicated in FIG. 3 and as will be described in more detail below, the second impedance matching circuit 38 may receive a control signal from the control circuit 22, wherein the control signal controls the second impedance matching circuit 38 to adapt its impedance.

It is to be understood that the first impedance matching circuit 34 may alternatively or additionally be connected into the transmission line 32, i.e. between the first point 62 and the second point 64.

Alternatively or additionally, the second impedance matching circuit 38 may be interconnected between the transmission line 32 and the common reference potential 60, i.e. between the contact point 58 and the common reference potential 60.

FIG. 4 schematically shows an example embodiment of an impedance matching circuit 40. For example, the first impedance matching circuit 34 and/or the second impedance matching circuit 38 described above may be established analogously or identical to the impedance matching circuit 40 described hereinafter.

As shown in FIG. 4, the impedance matching circuit 40 comprises a primary circuit 42 and a secondary circuit 44 that are coupled to each other by a transformer circuit 46. In the case of the first impedance matching circuit 34, the primary circuit 42 may be arranged between the contact point 58 to the transmission line 32 and the common reference potential 60, i.e. the primary circuit 42 may connect the transmission line 32 to the common reference potential 60. In the case of the second impedance matching circuit 38, the primary circuit 42 may be arranged between the input port 28 and the output port 30, i.e. the primary circuit 42 may connect the input port 28 with the output pot 30.

In an embodiment, the primary circuit 42 may be arranged between the first point 62 in the transmission line 32 and the second point 64 in the transmission line 32.

In an embodiment, the transformer circuit 46 comprises at least one primary winding 48 that is part of the primary circuit 42. The transformer circuit 46 further comprises a plurality of secondary windings 50 that are each connectable to the secondary circuit 44, as will be described in more detail below.

In general, the at least one primary winding 48 and the at least one secondary winding 50 each constitute an inductance that couple the primary circuit 42 with the secondary circuit 44.

It is noted that no direct electrical connection may be provided between the primary circuit 42 and the secondary circuit 44, i.e. the primary circuit 42 and the secondary circuit 44 may be galvanically isolated from each other. Alternatively, the primary circuit 42 and the secondary circuit 44 may be connected to a common reference potential, for example to the common reference potential 60.

In an embodiment, the secondary circuit 44 further comprises at least one reactance 52. The at least one reactance 52 may comprise at least one capacitor and/or at least one inductor. In an embodiment, an impedance of the at least one reactance may be constant or adjustable.

In an embodiment, the impedance matching circuit 40 further comprises a switching circuit 53 having a plurality of switches 54 being arranged in parallel. The switches 54 may be established, for example, as solid-state switches, as mechanical switches, as micro-electromechanical systems (MEMS) switches, as semiconductor switches, as PIN diodes, as MOSFETs, or other suitable type of electronic circuitry.

Each switch 54 of the plurality of switches 54 is configured to selectively connect at least one winding of the plurality of secondary windings 50 to the secondary circuit 44 or disconnect at least one winding of the plurality of secondary windings 50 from the secondary circuit 44. In an embodiment, each switch 54 of the plurality of switches 54 is configured to selectively connect at least one winding of the plurality of secondary windings 50 to the at least one reactance 52, or disconnect connect at least one winding of the plurality of secondary windings 50 from the at least one reactance 52.

Accordingly, the number of secondary windings 50 connected to the at least one reactance 52 can be adapted in a stepwise manner by appropriately controlling the switches 54 to connect and/or disconnect certain secondary windings 50.

Thereby, a transformation ratio of the transformer circuit 46 is adapted, such that the voltage applied to the at least one reactance 52 is adapted as well.

Accordingly, the at least one reactance 52 is coupled to and/or into the transmission line 32 in a defined manner, thereby adapting an impedance of the impedance matching network 20 in a defined manner.

In an embodiment, a driver circuit 56 may be provided for each switch 54, wherein the driver circuits 56 are configured to actuate the respectively associated switch 54. For example, the driver circuits 56 may apply a control voltage across control terminals of the respective switch 54, thereby actuating the respective switch 54. In an embodiment, the control voltage may be a DC voltage or an AC voltage.

In an embodiment, the control circuit 22 may control the driver circuits 56 to actuate the respectively associated switch 54 by providing corresponding control signals to the driver circuits 56. Accordingly, by actuating the switches 54, the secondary windings 50 can be selectively connected to the secondary circuit 44 or disconnected from the secondary circuit 44, as described above.

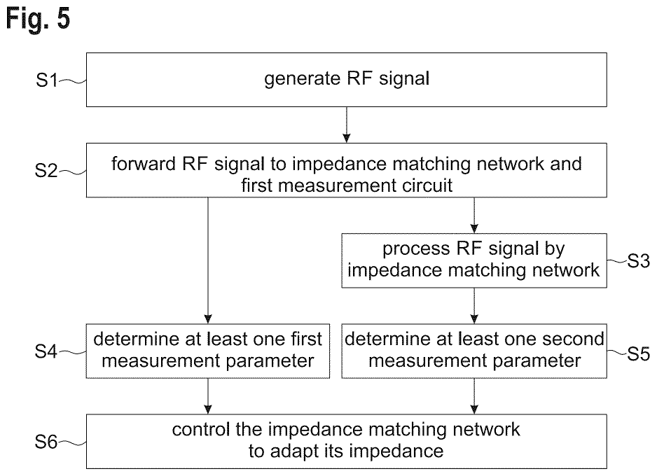

The plasma control system 10 described above is configured to perform an impedance matching method of matching an impedance for a plasma process, an example of which is hereinafter with reference to FIG. 5.

An RF signal is generated by the RF generator circuit 12 (step S1).

The RF signal is forwarded to and received by both the impedance matching network 20 and the first measurement circuit 24 (step S2).

Accordingly, the RF signal generated by the RF generator circuit 12 is an input signal of the impedance matching network 20.

Therein, the first measurement circuit 24 may be coupled to a signal path between the RF generator circuit 12 and the impedance matching network 20 upstream of the impedance matching network 20, for example by a directional coupler. Alternatively, the first measurement circuit 24 may be connected to the input port 28 of the impedance matching network 20.

The RF signal generated by the RF generator circuit 12 is processed by the impedance matching network 20, thereby obtaining an output signal (step S3).

The output signal of the impedance matching network 20 is forwarded to both the chamber feed unit 14 and to the second measurement circuit 26. Therein, the second measurement circuit 26 may be coupled to a signal path between the impedance matching network 20 and the chamber feed unit 14, for example by a directional coupler. Alternatively, the second measurement circuit 26 may be connected to the output port 30 of the impedance matching network 20.

At least one first measurement parameter is determined by the first measurement circuit 24 based on the input signal of the impedance matching network 20, i.e. based on the RF signal generated by the RF generator circuit 12 (step S4).

The at least one first measurement parameter may comprise an amplitude of the input signal, a phase of the input signal, and/or a power level of the input signal. The amplitude and phase of the input signal may relate to a voltage of the input signal or to a current of the input signal.

Further, at least one second measurement parameter is determined by the second measurement circuit 26 based on the output signal of the impedance matching network 20, i.e. based on the RF signal processed by the impedance matching network 20 (step S5).

The at least one second measurement parameter may comprise an amplitude of the output signal, a phase of the output signal, and/or a power level of the output signal. The amplitude and phase of the input signal may relate to a voltage of the output signal or to a current of the output signal.

Based on the at least one first measurement parameter and based on the at least one second measurement parameter, the control circuit 22 controls the impedance matching network 20 to adapt its impedance (step S6).

Therein, the control circuit 22 may control the first impedance matching circuit 34 and/or the second impedance matching circuit 38 to adapt their impedance. In an embodiment, the control circuit 22 may control the driver circuits 56 to selectively actuate the switches 54, thereby selectively connecting at least one winding of the plurality of secondary windings 50 to the at least one reactance 52 or disconnecting at least one winding of the plurality of secondary windings 50 from the at least one reactance 52.

If the impedance of the at least one reactance 52 is adaptable, the control circuit 22 may further control the at least one reactance 52 to adapt its impedance based on the at least one first measurement parameter and based on the at least one second measurement parameter.

In an embodiment, the control circuit 22 may determine an impedance of the impedance matching network 20 based on the at least one first measurement parameter and based on the at least one second measurement parameter. The control circuit 22 may compare the impedance determined with a target impedance of the impedance matching network 20 that is to be set. The control circuit 22 may control the impedance matching network 20 to adapt its impedance based on the comparison as described above.

It is noted that, in addition to adapting the impedance of the impedance matching network, the control circuit 22 may also control the RF generator circuit 12 to adapt a frequency of the RF signal generated. This allows to further fine-tune the transmission characteristics of the plasma control system 10 in order to maximize the energy transferred into the plasma 18.

In an embodiment, adapting the frequency of the RF signal generated mainly changes a reactance of the impedance matching network 20, i.e. an imaginary part of the impedance of the impedance matching network 20.

A real part of the impedance of the impedance matching network 20 may be affected by adapting the frequency of the RF signal generated but may change substantially less than the imaginary part.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a graphics processing unit (GPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

For example, the functionality described herein can be implemented by special purpose hardware-based computer systems or circuits, etc., or combinations of special purpose hardware and computer instructions. Each of these special purpose hardware-based computer systems or circuits, etc., or combinations of special purpose hardware circuits and computer instructions form specifically configured circuits, machines, apparatus, devices, etc., capable of implementing the functionality described herein.

Of course, in an embodiment, two or more of these components, or parts thereof, can be integrated or share hardware and/or software, circuitry, etc. In an embodiment, these components, or parts thereof, may be grouped in a single location or distributed over a wide area. In circumstances where the components are distributed, the components are accessible to each other via communication links.

In an embodiment, one or more of the components of the system 10 referenced above include circuitry programmed to carry out one or more steps of any of the methods disclosed herein. In an embodiment, one or more computer-readable media associated with or accessible by such circuitry contains computer readable instructions embodied thereon that, when executed by such circuitry, cause the component or circuity to perform one or more steps of any of the methods disclosed herein.

In an embodiment, the computer readable instructions includes applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably).

In an embodiment, computer-readable media is any medium that stores computer readable instructions, or other information non-transitorily and is directly or indirectly accessible by a computing device, such as processor circuitry, etc., or other circuity disclosed herein etc. In other words, a computer-readable medium is a non-transitory memory at which one or more computing devices can access instructions, codes, data, or other information. As a non-limiting example, a computer-readable medium may include a volatile random access memory (RAM), a persistent data store such as a hard disk drive or a solid-state drive, or a combination thereof. In an embodiment, memory can be integrated with a processor, separate from a processor, or external to a computing system.

Accordingly, blocks of the block diagrams and/or flowchart illustrations support various combinations for performing the specified functions, combinations of operations for performing the specified functions and program instructions for performing the specified functions. These computer program instructions may be loaded onto one or more computer or computing devices, such as special purpose computer(s) or computing device(s) or other programmable data processing apparatus(es) to produce a specifically-configured machine, such that the instructions which execute on one or more computer or computing devices or other programmable data processing apparatus implement the functions specified in the flowchart block or blocks and/or carry out the methods described herein. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

It will be appreciated that in one or more embodiments, the term computer or computing device can include, for example, any computing device or processing structure, including but not limited to a processor (e.g., a microprocessor), a central processing unit (CPU), a digital signal processor (DSP), an application-specific integrated circuit (ASIC), a field-programmable gate array (FPGA), a system on a chip (SoC), a graphics processing unit (GPU) or the like, or any combinations thereof.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

Although the method and various embodiments thereof have been described as performing sequential steps, the claimed subject matter is not intended to be so limited. As nonlimiting examples, the described steps need not be performed in the described sequence and/or not all steps are required to perform the method. Moreover, embodiments are contemplated in which various steps are performed in parallel, in series, and/or a combination thereof. As such, one of ordinary skill will appreciate that such examples are within the scope of the claimed embodiments.

In the detailed description herein, references to “one embodiment”, “an embodiment”, “an example embodiment”, “one or more embodiments”, “some embodiments”, etc., indicate that the embodiment or embodiments described may include a particular feature, structure, or characteristic, but every embodiment may not necessarily include the particular feature, structure, or characteristic. Moreover, such phrases are not necessarily referring to the same embodiment or embodiments. In addition, when a particular feature, structure, or characteristic is described in connection with an embodiment or embodiments, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

Where a range of values is provided, it is understood that each intervening value, to the tenth of the unit of the lower limit (unless the context clearly dictates otherwise), between the upper and lower limit of that range, and any other stated or intervening value in that stated range, is encompassed within the disclosure. The upper and lower limits of these smaller ranges may independently be included in the smaller ranges and are also encompassed within the disclosure, subject to any specifically excluded limit in the stated range. While the stated range includes one or both of the limits, ranges excluding either or both of those included limits are also included in the disclosure.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

1. An impedance matching network for plasma processes, comprising:
an input port being connectable to a radio frequency (RF) generator circuit;
an output port being connectable to a load;
a transmission line interconnecting the output port to the input port;
an impedance matching circuit comprising a primary circuit, a secondary circuit, at least one inductance, at least one reactance, and a switching circuit,
wherein the primary circuit is connected to the transmission line or is arranged in the transmission line,
wherein the secondary circuit comprises the at least one reactance,
wherein the at least one inductance is configured to couple the primary circuit with the secondary circuit, wherein the at least one inductance comprises a plurality of secondary windings being arranged at the secondary circuit, and
wherein the switching circuit is configured to selectively electrically connect at least one winding of the plurality of secondary windings to the secondary circuit or electrically disconnect at least one winding of the plurality of secondary windings from the secondary circuit.

2. The impedance matching network of claim 1, wherein the impedance matching circuit comprises a transformer circuit coupling the primary circuit with the secondary circuit, wherein the transformer circuit comprises the at least one inductance.

3. The impedance matching network of claim 2, wherein the transformer circuit comprises at least one primary winding, wherein the at least one primary winding is arranged at the primary circuit.

4. The impedance matching network of claim 1, wherein the at least one reactance comprises at least one capacitor.

5. The impedance matching network of claim 1, wherein the switching circuit comprises at least one solid-state switch.

6. The impedance matching network of claim 1, wherein the switching circuit comprises a plurality of switches being arranged in parallel, wherein each switch of the plurality of switches is configured to selectively connect at least one winding of the plurality of secondary windings to the secondary circuit or disconnect at least one winding of the plurality of secondary windings from the secondary circuit.

7. The impedance matching network of claim 6, wherein each switch of the plurality of switches is established as a solid-state switch.

8. The impedance matching network of claim 1, wherein the primary circuit is arranged between the input port and the output port.

9. The impedance matching network of claim 1, wherein the primary circuit is arranged between a contact point to the transmission line and a common reference potential.

10. The impedance matching network of claim 1, wherein the at least one reactance is adjustable.

11. A plasma control system comprising at least one impedance matching network according to claim 1.

12. The plasma control system of claim 11, further comprising at least one RF generator circuit, and at least one chamber feed unit, wherein the at least one chamber feed unit is configured to feed energy into plasma, wherein the input port of the at least one impedance matching network is connected to the at least one RF generator circuit, and wherein the output port of the at least one impedance matching network is connected to the at least one chamber feed unit.

13. The plasma control system of claim 11, further comprising a first measurement circuit, a second measurement circuit, and a control circuit,
wherein the first measurement circuit is connected to the at least one RF generator circuit, wherein the first measurement circuit is configured to determine at least one first measurement parameter based on at least one RF signal generated by the at least one RF generator circuit,
wherein the second measurement circuit is connected to the output port of the at least one impedance matching network, wherein the second measurement circuit is configured to determine at least one second measurement parameter based on at least one output signal of the at least one impedance matching network, and
wherein the control circuit is configured to control the at least one impedance matching network based on the at least one first measurement parameter and based on the at least one second measurement parameter.

14. An impedance matching method of matching an impedance for a plasma process, the impedance matching method comprising:
generating, by at least one RF generator circuit, at least one RF signal;
processing, by at least one impedance matching network, the at least one RF signal, thereby obtaining at least one output signal;
feeding the at least one output signal to at least one chamber feed unit;
determining, by a first measurement circuit, at least one first measurement parameter based on the at least one RF signal;
determining, by a second measurement circuit, at least one second measurement parameter based on the at least one output signal; and
controlling, by a control circuit, the at least one impedance matching network to adapt an impedance of the at least one impedance matching network based on the at least one first measurement parameter and based on the at least one second measurement parameter.

15. The impedance matching method of claim 14, wherein the impedance matching network comprises an input port being connected to the RF generator circuit,
wherein the impedance matching network further comprises an output port being connected to the chamber feed unit,
wherein the impedance matching network further comprises a transmission line, wherein the transmission line connects the output port to the input port,
wherein the impedance matching network comprises an impedance matching circuit,
wherein the impedance matching circuit comprises a primary circuit, a secondary circuit, at least one inductance, at least one reactance, and a switching circuit,
wherein the primary circuit is connected to the transmission line or is arranged in the transmission line,
wherein the secondary circuit comprises the at least one reactance,
wherein the at least one inductance is configured to couple the primary circuit with the secondary circuit, wherein the at least one inductance comprises a plurality of secondary windings being arranged at the secondary circuit, and
wherein the switching circuit is configured to selectively electrically connect at least one winding of the plurality of secondary windings to the secondary circuit or electrically disconnect at least one winding of the plurality of secondary windings from the secondary circuit.

16. The impedance matching method of claim 15, wherein the switching circuit is controlled to selectively electrically connect the at least one secondary winding of the plurality of windings to the secondary circuit or electrically disconnect the at least one winding of the plurality of windings from the secondary circuit by the control circuit based on the at least one first measurement parameter and based on the at least one second measurement parameter.
